(19) United States
(12) Patent Application Publication
(10) Pub. No.: US 2026/0244088 A1
(43) Pub. Date: Aug. 20, 2026

(54) EFFICIENT SILICON HARDMASK COMPOSITIONS AND METHODS FOR LITHOGRAPHIC MICROELECTRONIC STRUCTURE FABRICATION

(71) Applicant: Brewer Science, Inc., Rolla, MO (US)

(72) Inventors: Pengtao Lu, Suwanee, GA (US); Vandana Krishnamurthy, Rolla, MO (US); Xinlin Lu, Rolla, MO (US)

(21) Appl. No.: 19/542,157

(22) Filed: Feb. 17, 2026

Related U.S. Application Data
(60) Provisional application No. 63/759,165, filed on Feb. 16, 2025.

(51) Int. Cl. G03F 1/22; C07F 7/18; C08G 77/00; C08G 77/16; G03F 7/00; G03F 7/20; H10P 76/20

(52) U.S. Cl. CPC G03F 1/22; C07F 7/1892; C08G 77/16; G03F 7/2004; G03F 7/70008; C08G 77/80; H10P 76/204

(57) ABSTRACT

A composition for use in forming silicon hardmask layers is disclosed. The composition includes a nonpolymeric siloxane comprising a chromophore moiety, a polysiloxane, and optionally a thermal acid generator in a solvent system. The composition can be applied to a layer on substrate and heated to crosslink the polysiloxane, thus forming the silicon hardmask layer. A photoresist is then applied to the silicon hardmask layer, followed by DUV light exposure and development to form a pattern in the photoresist layer that is transferred to the silicon hardmask layer and other layers to the substrate. The composition minimizes chromophore sublimation and allows adjustments to the absorbance level needed for the particular application while also achieving manufacturing consistency.

### CROSS-REFERENCE TO RELATED APPLICATIONS

The present application claims the priority benefit of U.S. Provisional Patent Application Ser. No. 63/759,165, filed Feb. 16, 2025, entitled EFFICIENT SILICON HARDMASK COMPOSITIONS AND METHODS FOR LITHOGRAPHIC MICROELECTRONIC STRUCTURE FABRICATION, the entirety of which is incorporated by reference herein.

### BACKGROUND

### Field

The present invention relates generally to photolithography for forming microelectronic structures, and more specifically to compositions and methods for facilitating photolithographic pattern transfer through a photoresist into an underlying substrate.

### Description of Related Art

Photolithography has long been used to form small features in semiconductor substrates (e.g., silicon wafers and the like) during fabrication of microelectronic devices. In this process a mask is used to selectively expose some areas of a photoresist to light while other areas remain unexposed. Chemical changes in the photoresist triggered by the light allow pattern development in the photoresist. The resulting pattern is then transferred (e.g., etched) into the underlying substrate. It has been a common practice to apply bottom antireflective coatings under the photoresists to minimize undesired interference effects on the patterns caused by substrate reflections during exposure. Conventional antireflective coatings sometimes include one or more chromophores selected for their high absorbance at the exposure light wavelength. Over the years, photoresist films had to become much thinner to enable patterning smaller and smaller features. Eventually, as resist thickness decreased more and more, the resist no longer had enough etch resistance to complete pattern transfer. Thus, trilayer stacks were developed in which an intermediate silicon hardmask layer under the resist provides additional etch resistance and performs the antireflective function. A thick planarizing spin-on carbon (SOC) layer under the silicon hardmask layer constitutes the third layer of the trilayer stack. The etch rate differential between the silicon hardmask layer and the SOC layer is very high, allowing the SOC to serve as a pattern transfer layer.

Deep ultraviolet (DUV) lithography typically involves use of krypton-fluoride KrF (248 nm) or argon-fluoride ArF (193 nm) laser as the exposure light and remains commercially important although even shorter wavelength extreme ultraviolet (EUV) lithography has been developed. Functional groups having high aryl content, particularly two or more fused rings, are commonly used as chromophores for DUV lithography.

In addition to antireflective properties and good, consistent etch characteristics, silicon hardmasks must also meet other design requirements, including matching refractive index (n) in addition to absorbance (k) at the exposure wavelength. The precise values needed for (n) and (k) may vary depending on the thicknesses of the other material layers and other factors. Moreover, interactions between the silicon hardmask and the resist as well as between the silicon hardmask and the underlying SOC may need to be minimized, or in some cases intentional interactions controlled, to achieve optimal results.

It remains challenging to manufacture silicon hardmask compositions in a manner that consistently meets all the varying requirements for a range of different target applications with different specifications in an efficient and economical manner.

### SUMMARY

In some embodiments, the present disclosure is broadly concerned with a method of forming a microelectronic structure. The method comprises forming one or more intermediate layers on the surface of a substrate, with the one or more intermediate layers comprising an uppermost intermediate layer. A composition is applied to the uppermost intermediate layer so as to form a silicon hardmask layer on the uppermost intermediate layer. The composition comprises a nonpolymeric siloxane and a polysiloxane dissolved or dispersed in a solvent system, with the nonpolymeric siloxane comprising a chromophore moiety. A photoresist layer is formed on the silicon hardmask layer, and at least a portion of the photoresist layer is exposed to radiation having a wavelength of about 100 nm to about 300 nm.

In other embodiments, the disclosure provides a microelectronic structure comprising a substrate having a surface with one or more intermediate layers on the surface and there being an uppermost intermediate layer. A silicon hardmask layer is on the uppermost intermediate layer. The silicon hardmask layer comprises a polysiloxane and a nonpolymeric siloxane comprising a chromophore moiety. The polysiloxane is self-crosslinked and crosslinked with the nonpolymeric siloxane, and there is a photoresist layer on the silicon hardmask layer.

In further embodiments, a composition for forming a silicon hardmask layer for deep ultraviolet lithography is provided. The composition comprises a polysiloxane and a nonpolymeric siloxane dissolved or dispersed in a solvent system, with the nonpolymeric siloxane comprising a chromophore moiety.

### BRIEF DESCRIPTION OF THE DRAWINGS

FIG. 1 is a Gel Permeation Chromatography (GPC) graph of the material formed in Example 1;

FIG. 2 is a GPC graph of the material formed in Example 2;

FIG. 3 shows scanning electron microscope (SEM) images (200 kX) of Formulation 1's resist profiles in cross section at a tilt angle of 75 degrees (top) and 90 degrees (bottom), obtained as described in Example 8;

FIG. 4 shows SEM images (200 kX) of Formulation 2's resist profiles in cross section at a tilt angle of 75 degrees (top) and 90 degrees (bottom), obtained as described in Example 8;

FIG. 5 provides a comparison of the etch rate in CF₄ of the Example 7 material and a commercially available underlayer coating, as determined in Example 9;

FIG. 6 provides a comparison of the etch rate in O₂/N₂ of the Example 7 material and a commercially available underlayer coating, as determined in Example 9;

FIG. 7 is an SEM image of a cross-sectional view showing L/S pattern transfer (after HM open) with the hardmask formed from the Example 7 material on DUV 42 material underlayer (Example 9);

FIG. 8 is an SEM image of a cross-sectional view showing L/S pattern transfer (after SOC open) with the hardmask formed from the Example 7 material on DUV 42 material underlayer (Example 9);

FIG. 9 is an SEM image of a cross-sectional view showing L/S pattern transfer (after substrate open) with the hardmask formed from the Example 7 material on DUV 42 material underlayer (Example 9);

FIG. 10 is an SEM image of a cross-sectional view showing L/S pattern transfer (after 02 ash) with the hardmask formed from the Example 7 material on DUV 42 material underlayer (Example 9);

FIG. 11 provides a comparison of the etch rate in CF₄ of the Example 7 material and a commercially available underlayer coating, as determined in Example 10;

FIG. 12 provides a comparison of the etch rate in O₂/N₂ of the Example 7 material and a commercially available underlayer coating, as determined in Example 10;

FIG. 13 is an SEM image of a cross-sectional view showing contact hole pattern transfer (after HM open) with the hardmask formed from the Example 7 material on GF 110K material underlayer (Example 10);

FIG. 14 is an SEM image of a cross-sectional view showing contact hole pattern transfer (after SOC open) with the hardmask formed from the Example 7 material on GF 110K material underlayer (Example 10);

FIG. 15 is an SEM image of a cross-sectional view showing contact hole pattern transfer (after substrate open) with the hardmask formed from the Example 7 material on GF 110K material underlayer (Example 10); and

FIG. 16 is an SEM image of a cross-sectional view showing contact hole pattern transfer (after O₂ ash) with the hardmask formed from the Example 7 material on GF 110K material underlayer (Example 10).

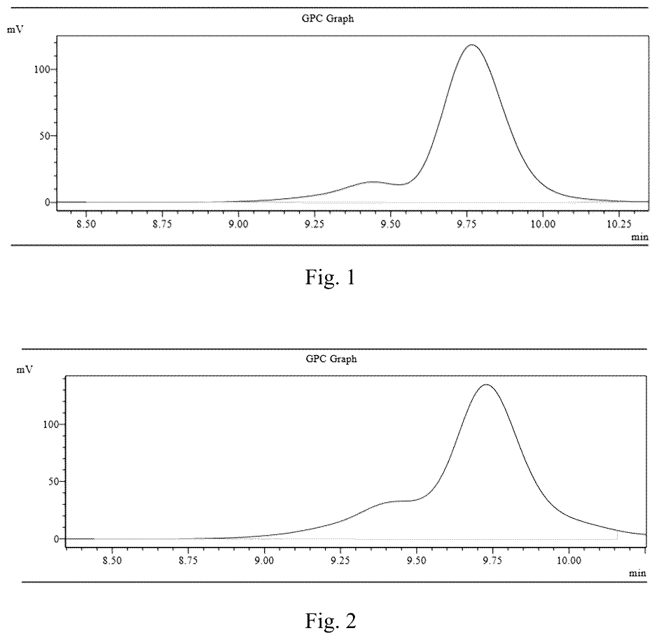

### DETAILED DESCRIPTION

The present disclosure is broadly concerned with a silicon hardmask composition and methods of using that composition. The composition comprises a nonpolymeric siloxane and a polysiloxane dissolved or dispersed in a solvent system.

### Composition

### 1. Nonpolymeric Siloxane

Preferred nonpolymeric siloxanes comprise a chromophore moiety. “Nonpolymeric” as used herein means monomers or oligomers having less than 5 repeat units. In more preferred embodiments, the nonpolymeric siloxanes described herein have no more than 2 repeat units, and in some instances only a single unit (i.e., the siloxane is monomeric).

The nonpolymeric siloxane can be formed by reacting a siloxane with a chromophore. Preferred siloxanes comprise at least one epoxy group. Suitable siloxanes include those chosen from 2-(3,4-epoxycyclohexyl) ethyl trimethoxy silane (ECHTMS), (3-glycidoxypropyl) trimethoxy silane (GOPTMS), 5,6-epoxyhexyltriethoxysilane (EHTES), (3-glycidoxypropyl) triethoxy silane (GOPTES), 3-glycidoxypropylmethyldiethoxysilane, 3-glycidoxypropylmethyldimethoxysilane, 2-(3,4-epoxycyclohexyl)ethyltriethoxysilane, or combinations thereof. In some embodiments, the siloxane is a monomer other than tetraethoxysilane.

Preferred chromophores are selected from those that absorb light at lithographic exposure wavelengths, such as wavelengths of about 100 nm to about 300 nm. Suitable chromophores comprise conjugated functional groups, such as aryls (e.g., C₆ to C₂₂) and/or conjugated polyenes (e.g., conjugated trienes, conjugated dienes). Suitable aryls present on the chromophore include phenyl groups and/or polycyclic aromatic hydrocarbons that can include up to 5 fused rings, and up to 4 fused rings in some embodiments. Preferred polycyclic aromatic hydrocarbons include naphthyls, anthracenyls, phenanthryls, fluorenyls, pyrenyls, chrysenyls, fluoranthenyls, benzofluorenyls, indenofluorenyls, perylenyls, or combinations thereof.

In one or more embodiments, the chromophore includes a nucleophilic group (e.g., —COOH) or other group that would allow the chromophore to be grafted to the selected siloxane.

Non-limiting examples of suitable chromophores having nucleophilic groups include those chosen from 1-hydroxy-2-naphthoic acid, 2-hydroxy-1-naphthoic acid, 6-hydroxy-2-naphthoic acid, 3-hydroxy-2-naphthoic acid, 1,4-dihydroxy-2-naphthoic acid, 3,5-dihydroxy-2-naphthoic acid, 3,7-dihydroxy-2-naphthoic acid, 3-hydroxy-2-anthracenecarboxylic acid, 1-hydroxy-2-anthracenecarboxylic acid, 9-anthracenecarboxylic acid, or combinations thereof.

This reaction generally involves combining the siloxane, chromophore, one or more suitable solvents, and optionally an initiator or reaction catalyst (e.g., benzyltriethylammonium chloride, tetrabutyl phosphonium bromide) in a reaction vessel subject to the required reaction conditions. The siloxane is typically added at a level of about 45% to about 65% by weight, preferably about 50% to about 60% by weight, and more preferably about 54% to about 58% by weight, based on the total solids in the reaction solution taken as 100% by weight. The chromophore is typically added at a level of about 30% to about 60% by weight, preferably about 35% to about 50% by weight, and more preferably about 38% to about 45% by weight, based on the total solids in the reaction solution taken as 100% by weight. In the same or different embodiments, it is preferred that the molar ratio of siloxane to chromophore is about 0.8:1 to about 1.2:1, preferably about 0.9:1 to about 1.1:1, and preferably about 1:1.

The initiator or reaction catalyst, if utilized, is typically included at a level of about 1% to about 3% by weight, and preferably about 1.5% to about 2.5% by weight, based on the total siloxane in the reaction solution taken as 100% by weight. Typical solvent levels are about 75% to about 95% by weight, and preferably about 80% to about 90% by weight, based on the total weight of all components in the reaction solution taken as 100% by weight, with the total solids level being the balance of these ranges.

Regardless of the particular components selected or the respective quantities thereof, the reaction materials are combined in the reaction vessel and stirred at a rate of about 50 rpm to about 500 rpm, while heating at a temperature of about 50° C. to about 150° C. (preferably about 50° C. to about 100° C.), typically for about 5 hours to about 24 hours. In embodiments where a nucleophile is present on the chromophore and an epoxy group is present on the siloxane, ring-opening occurs, and the nucleophile (e.g., carboxylic acid) grafts with or to the opened epoxy ring of the siloxane.

During the grafting reaction, it is preferred that substantially all of the chromophore is grafted to the siloxane and that substantially all of the siloxane is grafted to the chromophore. Preferably at least about 70%, more preferably at least about 80%, and still more preferably at least about 90% of the chromophore is grafted to the siloxane by the end of the reaction. The polydispersity index (PDI) of the nonpolymeric siloxane grafted with the chromophore is preferably less than about 1.5, more preferably less than about 1.3, and still more preferably less than about 1.2, as determined by gel permeation chromatography (GPC).

Once grafting is complete, the resulting nonpolymeric siloxane comprising a chromophore moiety suitably remains dissolved or dispersed in the reaction solvent(s). Adjustments to the solids content may be made, if desired. The reaction materials are preferably allowed to cool, transferred to a bottle, and stored in refrigeration until time needed to formulate the silicon hardmask composition, described in detail below.

The formed nonpolymeric siloxane preferably has a weight average molecular weight of about 900 Daltons or lower, preferably about 800 Daltons or lower, and more preferably about 700 Daltons or lower. The preferred minimum weight average molecular weight is about 500 Daltons or higher, and preferably about 600 Daltons or higher, with any minimum weight average molecular weight being combinable with any of the above maximum weight average molecular weights. Weight average molecular weight is determined using GPC as described in Example 1.

In some embodiments, the nonpolymeric siloxane comprises the structure

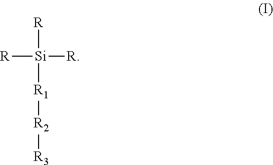

Each R of formula (I) is individually chosen from —H, alkoxys (preferably C₁ to C₈, more preferably C₁ to C₆, and even more preferably C₁ to C₄), or substituted or unsubstituted alkyls (preferably C₁ to C₈, more preferably C₁ to C₆, and even more preferably C₁ to C₄), with at least one R being an alkoxy. In other embodiments, at least two R groups are the same or different alkoxys. In yet further embodiments, all three R groups are the same or different alkoxys. As used herein, “individually chosen” means that each R can be the same, each R can be different, or two R groups can be the same while the third R group is different.

R₁ of formula (I) comprises a substituted or unsubstituted alkylene group (preferably C₁ to C₈, more preferably C₁ to C₆, and even more preferably C₁ to C₄).

R₂ of formula (I) comprises a chemical unit formed by the reaction between a siloxane and a chromophore when a chromophore is grafted to a siloxane. In one or more embodiments, this chemical unit is one that forms during the reaction between an epoxide ring and a nucleophile (e.g., a carboxylic acid group). Examples of two such chemical units include one or both of

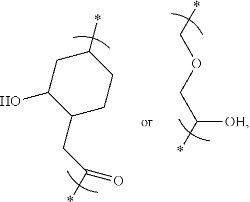

where the asterisk (*) shows the points of attachment to the rest of formula (I).

R₃ of formula (I) comprises a chromophore moiety. Suitable chromophore moieties include those comprising conjugated systems or conjugated functional groups, such as aryls (e.g., C₆ to C₂₂) and/or conjugated polyenes (e.g., conjugated trienes, conjugated dienes). Suitable aryls include phenyl groups and/or polycyclic aromatic hydrocarbons such as naphthyls, anthracenyls, phenanthryls, fluorenyls, pyrenyls, chrysenyls, fluoranthenyls, benzofluorenyls, indenofluorenyls, perylenyls, or combinations thereof.

### 2. Polysiloxane

Preferred polysiloxanes for use herein include one or more types of adhesion promoting monomers, one or more types of surface modification monomers, and/or one or more types of densification monomers.

Preferred adhesion promoting monomers include trialkoxysilanes (preferably C₁ to about C₆ alkoxys, and more preferably C₁ to about C₃ alkoxys) that include high-adhesion functional groups such as epoxies, anhydrides, acetamidos, and/or isocyanurates. Particularly preferred examples of the foregoing are chosen from (3-glycidoxypropyl)trimethoxysilane (GPTMS), 5,6-epoxyhexyltriethoxysilane (EPOTEOS), 2-(3,4-epoxycyclohexyl)-ethyltrimethyoxysilane (ECHTMS), [3-(triethoxysilyl)propyl]succinic anhydride (SucTEOS), (3-acetamidopropyl)trimethoxysilane (AmiTMS), (1,3-di-2-propen-1-yl)-5-(([3-triethoxysilylpropyl])-(1,3,5-triazine-2,4,6 (1H, 3H, 5H)-trione) (DAICA-TEOS), or mixtures thereof.

Preferred adhesion promoting monomers produce a polymer comprising a repeating unit having a structure chosen from one or both of:

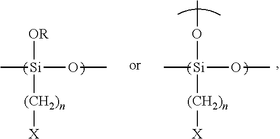

where:
each R is individually chosen from C₁ to about C₆ alkyls (preferably C₁ to about C₃ alkyls) or —H;
n is 1 to about 6, and more preferably 1 to about 3; and
each X is individually chosen from glycidoxy, epoxy, epoxycycloalkyl (preferably C₃ to about C₁₀ cycloalkyls, and preferably C₁ to about C₆ cycloalkyls), succinic anhydride, acetamido, or isocyanurate moieties.

Preferred surface modification monomers are chosen from methyltrimethoxysilane (MTMS), methyltriethoxysilane (MTEOS), dimethyldimethoxysilane (DMDMS), dimethyldiethoxysilane (DMDEOS), phenyltrimethoxysilane (PTMS), phenethyltrimethoxysilane (PETMS), 2-(carbomethoxy)ethyltrimethoxysilane (CMETMS), acetoxyethyltrimethoxysilane, ethyltrimethoxysilane, n-butyltrimethoxysilane (BuTMS), or mixtures thereof.

Preferred surface modification monomers produce a polymer comprising a repeating unit having a structure chosen from one or both of:

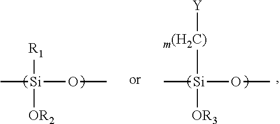

where:
each R₁ is individually chosen from C₁ to about C₆ alkyls (preferably C₁ to about C₃ alkyls) or C₆ to about C₂₀ aryls (preferably C₆ to about C₁₄ aryls);
each R₂ is individually chosen from C₁ to about C₆ alkyls (preferably C₁ to about C₃ alkyls) or —H;
each R₃ is individually chosen from C₁ to about C₆ alkyls (preferably C₁ to about C₃ alkyls) or —H;
m is 1 to about 6, and more preferably 1 to about 3; and
each Y is individually chosen from acetoxy, ester, or aryl moieties.

Preferred aryl moieties for Y are C₆ to about C₂₀, more preferably C₆ to about C₁₄, and even more preferably C₆.

Densification monomers for use in these polymers provide hydrophilic silanol groups and assist in providing thermally driven crosslinking during the post-application bake process by providing crosslinking sites for the structure of the final crosslinked polymer in the cured hardmask layer. Preferred densification monomers include tetraalkoxysilanes (preferably C₁ to about C₆ alkoxys, and more preferably C₁ to about C₃ alkoxys), with tetraethoxysilane (TEOS) and/or tetramethyl orthosilicate (TMOS) being particularly preferred.

Preferred densification monomers produce a polymer comprising a repeat unit having a structure chosen from one, two, or three of:

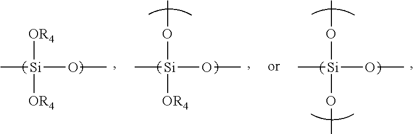

where each R4 is individually chosen from C₁ to about C₆ alkyls (preferably C₁ to about C₃ alkyls) or —H.

In one or more embodiments, the molar percentage of adhesion promoting monomers is preferably about 0.5% to about 10%, and more preferably about 1% to about 5%. The molar percentage of surface modification monomers is preferably about 10% to about 50%, and more preferably about 20% to about 40%. The molar percentage of densification monomers is preferably about 50% to about 80%, and more preferably about 60% to about 70%. It will be appreciated that the ratios and loading of monomers may be tuned to provide the appropriate properties of the final composition. Properties may be adjusted to accommodate various resist types, feature sizes, and/or feature types (line/space, contact holes, etc.).

In one embodiment, the polysiloxane is formed from monomers selected from the group consisting of tetraethoxysilane (TEOS), methyltrimethoxysilane (MTMS), phenyltrimethoxysilane (PTMS), and 2-(3,4-epoxycyclohexyl)ethyltrimethoxysilane (ECHTMS).

In some embodiments, the polysiloxane does not include any monomers that are not siloxanes. In the same or different embodiments, the polysiloxane consists essentially of, or consists of, one, two, or all three of the above-described adhesion promoting monomers, surface modification monomers, and/or densification monomers.

In one or more embodiments, the polysiloxane is substantially free (and preferably completely free) of aryl groups in the polymer backbone. Also, in some embodiments the polysiloxane is substantially devoid (and preferably completely devoid) of any ringed structures (e.g., such as fused carbon rings) in its polymer backbone. In the same or different embodiments, it is preferred that the polysiloxane does not include pendant groups (i.e., groups that are not part of the polymer backbone) that comprise conjugated functional groups or other conjugation.

To synthesize the polysiloxane, the desired monomer(s) is charged to a reactor with an optional distillation apparatus or reflux setup in an appropriate polymerization solvent with stirring. Polymerization solvents include propylene glycol monomethyl ether acetate (“PGMEA”), propylene glycol methyl ether (“PGME”), acetone, propylene glycol ethyl ether (“PGEE”), cyclohexanone, ethyl lactate, 3-methyl-1,5-pentanediol, 1,2-propylene glycol, 1,3-propylene glycol, ethylene glycol, or mixtures thereof. Monomer percent solids in the reaction mixture are preferably about 10% to about 40%, and more preferably about 25% to about 35%, based on the combined weight of all components in the reaction mixture (including monomers, catalysts, and solvent(s)) taken as 100% by weight.

A catalyst is then slowly charged to the reactor at a temperature of about 0° C. to about 50° C., and preferably about 5° C. to about 25° C. Suitable catalysts for polymerization include, but are not limited to, nitric acid, hydrochloric acid, acetic acid, trifluoroacetic acid, sulfonic acid, or combinations thereof. The catalyst is suitably added as a solution in water. The catalyst solutions are prepared in water preferably as about 0.001N to about ION solutions, more preferably about 0.01N to about 5N solutions, and even more preferably about 3N solutions for weaker acids and about 0.01N solutions for stronger acids. These aqueous catalyst solutions are added in an amount of preferably about 0.5 equivalents to about 20 equivalents, more preferably about 5 equivalents to about 15 equivalents, and even more preferably about 10 equivalents to the total monomers, where one equivalent is approximately equal to one mole of water per mol of monomer (or to about 18 grams of water per mole of monomer). The reaction mixture is allowed to stir at about 50 rpm to about 500 rpm for preferably about 5 hours to about 24 hours at a temperature of from about 25° C. to about 100° C., more preferably from about 50° C. to about 80° C. The reaction is optionally performed in an inert atmosphere such as nitrogen.

If desired, the polysiloxane is purified and/or isolated by a rotary evaporator process (also referred to as “rotavap” or “rotavaped” herein). In this process, the reaction mixture is processed in a rotary evaporator and is processed at a temperature of about 20° C. to about 50° C., and preferably about 30° C. to about 45° C. The rotary evaporation process is performed until the solvent is removed. Prior to rotary evaporation, a cosolvent may be added to the reaction mixture, if desired. Suitable cosolvents include, but are not limited to, PGEE, PGMEA, PGME, or combinations thereof.

The number average molecular weight (Mn) of the resulting polysiloxane as measured by GPC using polystyrene standards is preferably about 700 Daltons to about 3,000 Daltons, and more preferably about 1,000 Daltons to about 2,000 Daltons. The weight-average molecular weight (Mw) range of the polysiloxane as measured by GPC using the procedure described in Example 1 is preferably about is 1,000 Daltons to about 10,000 Daltons, more preferably about 1,200 Daltons to about 8,000 Daltons, and even more preferably about 1,500 Daltons to about 5,000 Daltons.

### 3. Formulation

To form the final silicon hardmask composition, the nonpolymeric siloxane and polysiloxane as described above are dispersed or dissolved in a solvent system along with any optional ingredients. The weight ratio of nonpolymeric siloxane to polysiloxane is selected to achieve the desired absorbance characteristics for a particular application and is preferably about 1:5 to about 1:1, more preferably about 1:4 to about 1:1, even more preferably about 1:3 to about 1:1, and still more preferably about 1:2 to about 1:1.

Preferred solvent systems include one or more solvents such as propylene glycol methyl ether acetate, propylene glycol methyl ether, propylene glycol ethyl ether, propylene glycol n-propyl ether, ethyl lactate, cyclohexanone, gamma-butyrolactone, gamma-valerolactone, 3-methyl-1,5-pentanediol, 1,2-propylene glycol, 1,3-propylene glycol, ethylene glycol, or mixtures thereof. The solvent system is preferably used at a level of about 90% to about 99% by weight, more preferably about 95% to about 99% by weight, and even more preferably about 95% to about 98.5% by weight solvent, based upon the total weight of the composition taken as 100% by weight. The silicon hardmask composition preferably comprises a solids content of about 1% to about 10% by weight, more preferably about 1.5% to about 5% by weight, and even more preferably about 1.5% to about 2.5% by weight solids, based upon the total weight of the composition taken as 100% by weight.

Exemplary optional ingredients include surfactants, mineral acids, organic acids, grafting/condensation catalysts, thermal acid generators (“TAGs”), photoacid generators (“PAGs”), inhibitors, and/or pH regulators.

When used, suitable TAGs include quaternary ammonium blocked super acids, such as quaternary ammonium blocked triflic acid. Examples of such commercially available TAGs include those sold under the name K-PURE® TAG-2689, K-PURE® TAG-2678, K-PURE® TAG-2700, K-PURE® CXC-1889, K-PURE® CXC 1821, K-PURE® TAG-2789, or combinations thereof, all available from King Industries, Inc., Norwalk, Conn. When utilized, the TAG is present in the composition in an amount of about 0.1% to about 5% by weight, more preferably about 0.5% to about 3% by weight, and even more preferably about 1% to about 3% by weight, based upon the total weight of the solids taken as 100% by weight.

When used, suitable pH regulators include maleic acid, malonic acid, malic acid, or combinations thereof. The pH regulators may be included to slow aging and/or improve spin-bowl compatibility. When utilized, the pH regulator is present in the composition in an amount of about 0.1% to about 5% by weight, more preferably about 0.5% to about 3% by weight, and even more preferably about 1% to about 3% by weight, based upon the total weight of the solids taken as 100% by weight.

In some embodiments, the composition comprises less than about 2% by weight, preferably less than about 1% by weight, and more preferably about 0% by weight of a polymer other than the polysiloxane. Additionally or alternatively, in one or more embodiments the composition comprises less than about 2% by weight, preferably less than about 1% by weight, and more preferably about 0% by weight of silsesquioxane resins.

In one or more embodiments, the composition comprises less than about 1% by weight, preferably less than about 0.5% by weight, and more preferably about 0% by weight of a crosslinking agent. Additionally or alternatively, in one or more embodiments the composition comprises less than about 0.5% by weight, and more preferably about 0% by weight of a photoacid generator.

In some embodiments, the composition consists essentially of, or even consists of, the nonpolymeric siloxane comprising the chromophore moiety, the polysiloxane, and solvent system.

In other embodiments, the composition consists essentially of, or even consists of, the nonpolymeric siloxane comprising the chromophore moiety, the polysiloxane, a catalyst (e.g., TAG, PAG), and solvent system.

In other embodiments, the composition consists essentially of, or even consists of, the nonpolymeric siloxane comprising the chromophore moiety, the polysiloxane, a catalyst (e.g., TAG, PAG), solvent system, and one or more of a surfactant, mineral acid, organic acid, inhibitor, and/or pH regulator.

### Method of Using the Composition

The above-described silicon hardmask compositions can be used to form a silicon hardmask layer in a microelectronic structure using lithography processes. Broadly, a silicon hardmask composition as described herein is formed into a layer on a substrate surface, or on an intermediate layer (described below) present on the substrate surface, followed by crosslinking or curing of the composition to form the silicon hardmask layer. The resulting silicon hardmask layer provides antireflective and other desired optical properties at the exposure wavelength of interest as well as etch resistance during pattern transfer.

In more detail, any microelectronic substrate can be used. The substrate is preferably a semiconductor substrate, such as silicon, SiGe, SiO₂, Si₃N₄, SiON, SiCO:H (such as that sold under the name Black Diamond, by SVM, Santa Clara, Calif., US), tetramethyl silate and tetramethyl-cyclotetrasiloxane combinations (such as that sold under the name CORAL), aluminum, tungsten, tungsten silicide, gallium arsenide, germanium, tantalum, tantalum nitride, Ti₃N₄, hafnium, HfO₂, ruthenium, indium phosphide, coral, and/or glass. The substrate can have a planar surface, or it can include topographic features (via holes, trenches, contact holes, raised features, lines, etc.). As used herein, “topography” refers to the height or depth of a structure in or on a substrate surface.

The substrate surface may be primed prior to hardmask or other layer formation, if desired. Preferred primers include hexamethyldisilizane (“HMDS”). In this process, the wafer is exposed to a vapor of the primer in a sealed chamber while heating at 150° C. for 90 seconds. As used herein, a primed surface is considered to be an intermediate layer, even if the priming process simply results in a surface modification of the layer being primed rather than the formation of a distinct layer.

As noted above, optional intermediate layers may be formed on the (primed or unprimed) substrate surface prior to hardmask layer formation, with the hardmask layer ultimately being formed on the uppermost intermediate layer. In some embodiments, a carbon-rich layer is one such intermediate layer that may be formed on top of the substrate or any intermediate layers. The carbon-rich layer can be formed by any known application method, with one preferred method being spin-coating at speeds of about 1,000 to about 5,000 rpm, and preferably about 1,250 to about 1,750 rpm, for a time period of about 30 to about 120 seconds, and preferably about 45 to 75 seconds. The term “carbon-rich” refers to layers formed from compositions comprising greater than about 50% by weight carbon, preferably greater than about 70% by weight carbon, and more preferably about 75 to about 80% by weight carbon, based upon the total solids in the composition taken as 100% by weight. (Because the foregoing % by weight carbon ranges are based on solids in the hardmask composition, the same % by weight ranges apply to the formed layer as well.) Suitable carbon-rich layers are selected from the group consisting of spin-on carbon layers (“SOC”), amorphous carbon layers, and carbon planarizing layers.

Exemplary carbon-rich layers will generally comprise a polymer dissolved or dispersed in a solvent system, along with the following optional ingredients: acid and/or base quenchers, catalysts, crosslinking agents, and/or surface modification additives. Preferred compositions will be suitable for forming thick layers and preferably have solids content of about 0.1% to about 70%, more preferably about 5% to about 40%, and even more preferably about 10% to about 30% by weight, based upon the total weight of the composition taken as 100% by weight, with the balance being solvent. Suitable solvents include those mentioned above with respect to the silicon hardmask composition.

After the carbon-rich composition is applied, it is preferably heated to a temperature of about 100° C. to about 400° C., and more preferably about 160° C. to about 350° C., for a time period of about 30 seconds to about 120 seconds, and preferably about 45 seconds to about 60 seconds, to evaporate solvents. The thickness of the carbon-rich layer after baking is preferably about 10 nm to about 120 nm, more preferably about 20 nm to about 100 nm, and even more preferably about 50 nm to about 60 nm. The carbon-rich layer may be formed by other known application methods, such as chemical vapor deposition (“CVD”), plasma-enhanced chemical vapor deposition (“PECVD”), atomic layer deposition (“ALD”), or plasma-enhanced atomic layer deposition (“PEALD”).

The inventive silicon hardmask layer can be formed by any known application method, either directly on the substrate surface (primed or unprimed) or on the carbon-rich layer, if utilized. In one or more embodiments, the uppermost intermediate layer on which the hardmask layer is formed is not a dielectric layer (e.g., not formed of SiO₂, HfO₂, Si₃N₄, ZrO₂, Ta₂O₅, TiO₂, La₂O₃, SiOC, SiCN, p-OSG, SiGe, SiON, and/or Al₂O₃). One preferred application method involves spin-coating the hardmask composition at speeds of about 1,000 rpm to about 2,000 rpm, and preferably about 1,250 to about 1,750 rpm, for a time period of about 15 seconds to about 120 seconds, and preferably about 30 seconds to about 75 seconds.

After the silicon hardmask composition is applied, it is preferably heated to a temperature of about 150° C. to about 300° C., and more preferably about 200° C. to about 250° C., for a time period of about 15 seconds to about 120 seconds, and preferably about 30 seconds to about 75 seconds, to evaporate solvents. In one or more embodiments, the polysiloxane crosslinks during this heating to form a crosslinked polymer network within the hardmask layer. Preferably, the nonpolymeric siloxane having the chromophore moiety also crosslinks with the polysiloxane (and/or potentially itself) during this time. Thus, the final hardmask layer may comprise self-crosslinked polysiloxane, self-crosslinked nonpolymeric siloxane, polysiloxane crosslinked with nonpolymeric siloxane, or a combination of two or three of the foregoing.

The thickness of the hardmask layer after baking is preferably about 20 nm to about 200 nm, more preferably about 40 nm to about 150 nm, and even more preferably about 50 nm to about 100 nm. The hardmask layer should have an etch rate at least about 1.5 times that of the photoresist (e.g., a chemically amplified, metal oxide, or chain scission-type photoresist) in a fluorine-rich (e.g., CF₄) plasma atmosphere. Additionally or alternatively, the previously described carbon-rich layer should etch at least about 1.5 times faster than the hardmask layer in an oxygen-rich (e.g., O₂) plasma etch atmosphere. The hardmask layer should have an etch rate in O₂ that is sufficiently slow to act as an etch block and allow pattern transfer into the carbon-rich layer.

In one embodiment, the silicon hardmask layer will preferably have a surface energy of about 30 mN/m to about 50 mN/m, and more preferably about 25 mN/m to about 60 mN/m, determined by performing surface contact angle measurements with multiple liquids (e.g., water and diiodomethane) on a contact angle tool such as a VCA Optima contact angle tool.

The silicon hardmask layer will typically have an n value of about 1.40 to about 1.50, and preferably about 1.44 to about 1.49 at a thickness of about 50 nm and a wavelength of about 248 nm. The silicon hardmask layer will typically have a k value of less than about 0.30, preferably about 0 to about 0.28, and more preferably about 0 to about 0.2 at a thickness of about 50 nm and a wavelength of about 248 nm.

The cured hardmask layer will be substantially insoluble in typical organic solvents such as ethyl lactate, propylene glycol methyl ether acetate, propylene glycol methyl ether, propylene glycol n-propyl ether, cyclohexanone, acetone, gamma butyrolactone, and mixtures thereof. Thus, when subjected to a stripping test, the cured hardmask will preferably have a percent stripping of less than about 5%, more preferably less than about 1%, and still more preferably about 0%. The stripping test involves first determining the thickness (by taking the average of measurements at five different locations using ellipsometry) of the cured layer. This average is the initial average film thickness. Next, a solvent (e.g., propylene glycol methyl ether acetate) is puddled onto the cured film for about 20 seconds, followed by spin drying at about 3,000 rpm for about 30 seconds to remove the solvent. The thickness is measured again at five different points on the wafer using ellipsometry, and the average of these measurements is determined. This average is the final average film thickness. The amount of stripping is the difference between the initial and final average film thicknesses. The percent stripping is:

$$\% stripping = ( \frac{amount of stripping}{initial average film thickness} ) \times 100.$$

In some embodiments, after the silicon hardmask layer is baked, a priming process may be used on the upper surface of the silicon hardmask layer before coating with a photoresist. Preferred primers include hexamethyldisilizane. In this process, the wafer is exposed to vapor of the primer in a sealed chamber while heating at 150° C. for 90 seconds. When the silicon hardmask layer is primed as described herein, it is considered to be a surface modification, and it is not considered to be an additional or distinct layer on the hardmask layer.

Next, and regardless of whether the silicon hardmask layer was primed, a photoresist (i.e., imaging layer) can be applied to the silicon hardmask layer to form a photoresist layer. Preferred photoresists are DUV photoresists, meaning that the photoresist can be patterned at wavelengths of about 100 nm to about 300 nm, and particularly at KrF (248 nm) and/or ArF (193 nm) wavelengths. The photoresist layer can be formed by any conventional method, with one preferred method being spin coating the photoresist composition at speeds of about 350 rpm to about 4,000 rpm (preferably about 1,000 rpm to about 2,500 rpm) for a time period of about 10 seconds to about 60 seconds (preferably about 10 seconds to about 30 seconds). The photoresist layer is then optionally post-application baked (“PAB”) at a temperature of at least about 70° C., preferably about 80° C. to about 150° C., and more preferably about 100° C. to about 150° C., and for time periods of about 30 seconds to about 120 seconds. The average thickness (average measurements taken over five locations by an ellipsometer) of the photoresist layer after baking will typically be about 200 nm to about 600 nm, preferably from about 300 nm to about 500 nm, and more preferably about 350 nm to about 450 nm.

The photoresist layer is subsequently patterned by exposure to DUV light (e.g., at wavelengths preferably of from about 100 nm to about 300 nm). More specifically, the photoresist layer is exposed using a mask positioned above the surface of the photoresist layer. The mask has areas designed to permit the light to pass through the mask and contact the surface of the photoresist layer. The remaining portions of the mask are designed to absorb or block the light to prevent the radiation from contacting the surface of the photoresist layer in certain areas. Those skilled in the art will readily understand how to use this exposure process to generate a desired pattern.

After exposure, the photoresist layer is preferably subjected to a post-exposure bake (“PEB”) at a temperature of about 180° C. or lower, preferably about 60° C. to about 140° C., and more preferably about 80° C. to about 130° C., for a time period of about 30 seconds to about 120 seconds (preferably about 30 seconds to about 90 seconds).

The photoresist layer is then contacted with a developer to form the desired pattern. Depending upon whether the photoresist used is positive-working or negative-working, the developer will either remove the exposed portions of the photoresist layer or remove the unexposed portions of the photoresist layer to form the pattern. The pattern is then transferred to the silicon hardmask layer, any present intermediate layers, and finally the substrate. This pattern transfer can take place via plasma etching (e.g., CF₄ etchant, 02 etchant) or a wet etching or developing process. In embodiments where the pattern will be transferred from the photoresist layer to the substrate via etching, it is preferred that the etch rate of the silicon hardmask layer in CF₄ relative to a typical photoresist (e.g., a polyhydroxystyrene-based photoresist such as that sold under the name M91Y-9CP by JSR Micro, Inc.) is at least about 1×, and preferably about 1.5× to about 2× that of the typical photoresist.

The use of the silicon hardmask compositions described herein offers a number of advantages. For example, one advantage is that the nonpolymeric siloxane provides bulk that limits chromophore loss from the hardmask composition or layer before lithographic exposure (e.g., during baking or curing steps). As a result, less chromophore is needed to achieve the same level of absorbance.

Additionally, the silicon hardmask compositions described herein provides numerous advantages in terms of manufacturability and flexibility. For example, the nonpolymeric siloxane comprising a chromophore moiety can be more readily manufactured economically and with high consistency compared to grafting the chromophore onto a polymer. That is, the bulkiness of the chromophore can make copolymerization of chromophore-containing monomers a significant challenge. Also, the ratio of nonpolymeric siloxane comprising a chromophore moiety to polysiloxane can be easily adjusted during the blending process to control the absorbance characteristics of the resulting hardmask layer. Thus, the same two base materials (and only two unchanging base-material manufacturing processes) can be used to support a wide variety of applications. If the chromophore were grafted to a polymer, adjustments to the absorbance level needed to support these various applications would require repeated adjustments to the manufacturing process that are more complicated, making it difficult to achieve consistent manufacturing results while adjusting the chromophore loading.

Additional advantages of the various embodiments will be apparent to those skilled in the art upon review of the disclosure herein and the working examples below. It will be appreciated that the various embodiments described herein are not necessarily mutually exclusive unless otherwise indicated herein. For example, a feature described or depicted in one embodiment may also be included in other embodiments but is not necessarily included. Thus, the present disclosure encompasses a variety of combinations and/or integrations of the specific embodiments described herein.

As used herein, the phrase “and/or,” when used in a list of two or more items, means that any one of the listed items can be employed by itself or any combination of two or more of the listed items can be employed. For example, if a composition is described as containing or excluding components A, B, and/or C, the composition can contain or exclude A alone; B alone; C alone; A and B in combination; A and C in combination; B and C in combination; or A, B, and C in combination.

The present description also uses numerical ranges to quantify certain parameters relating to various embodiments. It should be understood that when numerical ranges are provided, such ranges are to be construed as providing literal support for claim limitations that only recite the lower value of the range as well as claim limitations that only recite the upper value of the range. For example, a disclosed numerical range of about 10 to about 100 provides literal support for a claim reciting “greater than about 10” (with no upper bounds) and a claim reciting “less than about 100” (with no lower bounds).

### EXAMPLES

The following examples set forth methods in accordance with the disclosure. It is to be understood, however, that these examples are provided by way of illustration, and nothing therein should be taken as a limitation upon the overall scope.

### Example 1

### Reaction of ECHTMS and 9-ACA

In this Example, 27.10 g of 2-(3,4-epoxycyclohexyl)ethyltrimethoxysilane (ECHTMS), 20.00 g of 9-anthracenecarboxylic acid (9-ACA), 0.55 g of benzyltriethylammonium chloride (BTEAC), and 250 g of PGME were weighed out in a 300-mL jacketed reactor. The reactor was equipped with reflux condenser and purged with nitrogen. The suspension was stirred at 400 rpms for 5 minutes. The temperature of the jacket was raised to 110° C. in 60 minutes. After that, the solution was stirred while the jacket was held at 110° C. for 24 hours. The reactor contents were allowed to cool and then downbottled into an Aicello bottle. The bottle was stored in refrigeration.

The products of Example 1 were analyzed using gel permeation chromatography (GPC) measurement (SCL40 Shimadzu GPC, Column: Agilent. Serial No. 0006795884-255, Mobile phase: Tetrahydrofuran, Detector: Differential Refractive Index, Flow rate 1 mL/min, column oven temperature: 40° C. with a maximum of 60° C.), which found the weight average Mw to be about 600-700 Da. The GPC spectrum was multimodal (FIG. 1).

High-performance liquid chromatography (HPLC) also indicated the presence of multiple products. HPLC equipment and parameters: Shimadzu 2040C (Reverse phase), Column: C18XB, Mobile phase: H₃PO₄(90)/ACN(10), Flow rate: 1.0 mL/min, Column temperature: 30° C.

Scheme A shows the reaction that took place in this Example 1.

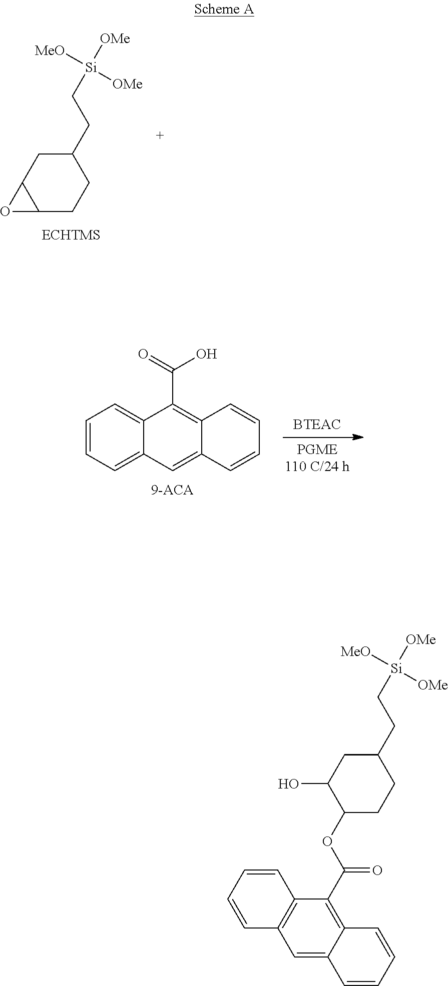 [SMILES: CO[Si](CCC1CCC2OC2C1)(OC)OC ; O=C(O)c1c2ccccc2cc2ccccc12 ; CO[Si](CCC1CCC(OC(=O)c2c3ccccc3cc3ccccc23)C(O)C1)(OC)OC]

### Example 2

### Reaction of GOPTMS and 9-ACA

In this Example, 26.00 g of (3-glycidoxypropyl)trimethoxysilane (GOPTMS), 20.00 g of 9-anthracenecarboxylic acid (9-ACA), 0.55 g of BTEAC, and 250 g of PGME were weighed out in a 300-mL jacketed reactor. The reactor was equipped with a reflux condenser and purged with nitrogen. The suspension was stirred at 400 rpm for 5 minutes. The temperature of the jacket was raised to 110° C. in 60 minutes while stirring continued. After that, stirring continued while the jacket was held at 110° C. for 24 hours. Afterward, the reactor contents were allowed to cool and transferred to a 1-L Aicello bottle, which was stored in refrigeration.

The products of Example 2 were analyzed using GPC measurements similar to that described in Example 1, which found the weight average Mw to be about 600-700 Da. The GPC spectrum was multimodal. HPLC measurements were carried out similar to those described with Example 1, and these results also indicated the presence of multiple products. Scheme A shows the reaction that took place in this Example 2.

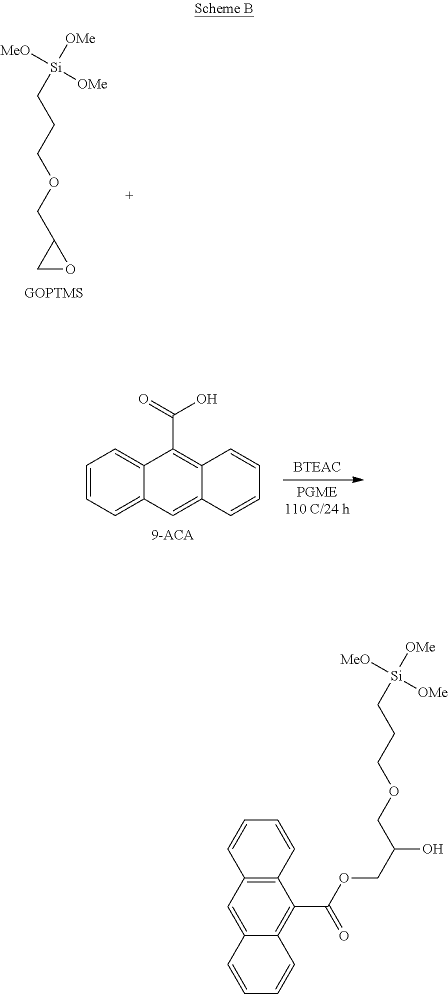 [SMILES: CO[Si](CCCOCC1CO1)(OC)OC ; O=C(O)c1c2ccccc2cc2ccccc12 ; CO[Si](CCCOCC(O)COC(=O)c1c2ccccc2cc2ccccc12)(OC)OC]

### Example 3

### High-TEOS Siloxane Polymer

In this Example, 0.81 g of 2-(3,4-epoxycyclohexyl)ethyltrimethoxysilane (ECHTMS), 5.23 g of phenyltrimethoxysilane (PTMS), 9.44 g of methyltrimethoxysilane (MTMS), and 48.12 g of tetraethoxysilane (TEOS) were added to 57 g of PGME in a three-necked round bottom flask. The flask was placed in an oil bath and equipped with a distillation set up. The whole reaction was purged with nitrogen. Next, 29.70 g of 0.01M nitric acid were dropwise added into the reaction solution while it was stirred at 250 rpm at room temperature. After the addition of nitric acid, the temperature of the oil bath was gradually increased to 70° C. The reaction solution was held at 70° C. for seven hours, after which the reaction was allowed to cool to room temperature. Then the contents of the flask were transferred to an Aicello bottle, which was stored at −20° C.

The products of Example 3 were analyzed using GPC measurements similar to those described with Example 1, which found the Mw to be about 2,000-2,500 Da. The GPC spectrum was monomodal.

### Example 4

### Purification of High-TEOS Siloxane Polymer

The solution produced in Example 3 was transferred to a round bottom flask. The flask was placed on a rotavapor with water bath temperature set at 30° C. The residual by products (EtOH/MeOH/H₂O) were removed under reduced pressure (15 torr) using the rotavap. Finally, the concentrated solution was diluted with more PGME to restore the % solids of the solution to the same % solids as before the rotavap. The solution was transferred to an Aicello bottle, which was stored at −20° C.

The purified product of this Example 4 was analyzed using GPC measurement similar to those described in Example 1, which found the Mw to be about 2,000-2,500 Da. The GPC spectrum was monomodal.

### Example 5

### Formulation 1 (60/40 Ratio)

In this Example, 5.71 g of the product of Example 3 (% solids ~17.62% in PGME) and 3.38 g of the product from Example 1 (% solids ~19.84% in PGME) were weighed out in a 100-ml Aicello bottle. Then, 3.35 g of maleic acid solution (% solids ~0.5% in PGME) and 16.77 g of K-Pure® TAG-2689 solution (% solids ~0.1% in of PGME) were also added into the same bottle. Finally, 41.31 g of PGME, 9.83 g of water, and 19.66 g of PGMEA were weighed out in the same bottle to dilute the formulation. The resulting formulation was mixed on a roller for 60 minutes to assure homogeneous mixing after which then the solution was purged through a 0.1-μm filter. The filtered solution was transferred to a 100-ml Aicello bottle and refrigerated.

The solution was applied to a bare silicon wafer by spin coating at 1,500 rpm for 60 seconds. The film was then baked at 205° C. for 60 seconds. The thickness of the film was about 50 nm after baking. The film was resistant to both organic solvent (e.g., PGME or PGMEA) and resist developer (PD523), as determined by puddling for 20 seconds, then spinning for 45 seconds at 1,500 rpm, and then re-measuring thickness. The coated wafer was run on a VASE M2000 ellipsometer to obtain raw optical data. The data was then fit for thickness, and the n and k values at 248 nm were about 1.47 and 0.27, respectively.

### Example 6

### Formulation 2 (80/20 Ratio)

In this Example, 7.61 g of the product of Example 3 (% solids ~17.62% in PGME) and 1.69 g of the product of Example 1 (% solids ~19.84% in PGME) were weighed out in a 100-ml Aicello bottle. Then, 3.35 g of maleic acid solution (solid % ~0.5% in 100% of PGME) and 16.77 g of K-Pure® TAG-2689 solution (solid % ~0.1% in 100% of PGME) were also added to the same bottle. Finally, 41.09 g of PGME, 9.83 g of water, and 19.66 g of PGMEA were weighed out in the same bottle to dilute the formulation. The resulting formulation was left on the roller for 60 minutes to assure homogeneous mixing. The solution was then purged through a 0.1-μm filter, and the filtered solution was transferred to a 100-ml Aicello bottle and stored in refrigeration.

The solution was applied to a bare silicon wafer by spin coating at 1,500 rpm for 60 seconds. The film was then baked at 205° C. for 60 seconds. The thickness of the film was about 50 nm after baking. The film was resistant to both organic solvent and resist developer (PD523), tested as described in Example 5. The n and k values (determined as described in Example 5) at 248 nm were about 1.49 and 0.14, respectively.

### Example 7

### Formulation 3 (55/45 Ratio)

In this Example, 5.76 g of the product of Example 4 (% solids ~17.78% in PGME) and 4.20 g of the product of Example 1 (% solids ~19.98% in PGME) were weighed out in a 100-ml Aicello bottle. Then, 3.73 g of maleic acid solution (solid % ~0.5% in 100% of PGME) and 3.73 g of K-Pure® TAG-2689 solution (% solid ~0.5% in PGME) were also added to the same bottle. Finally, 53.16 g of PGME, 9.81 g of water, and 19.62 g of PGMEA were weighed out in the same bottle to dilute the formulation. The resulting formulation was left on a roller for about 60 minutes to assure homogeneous mixing. The solution was purged through a 0.1-μm filter, after which the filtered solution was transferred to a 100-ml Aicello bottle and stored in refrigeration.

The solution was applied to a bare silicon wafer by spin coating at 1,500 rpm for 60 seconds. The film was then baked at 205° C. for 60 seconds. The thickness of the film was about 50 nm after baking. The film was resistant to both organic solvent and resist developer (PD523), tested as described in Example 5. The n and k values (determined as described in Example 5) at 248 nm are about 1.47 and 0.28, respectively.

### Example 8

### Summary of Lithography Results of Formulations 1 and 2

The materials produced in Examples 5 and 6 were used to form silicon hardmasks on top of a spin-on carbon material and under a photoresist in a trilayer stack and tested for DUV lithography and pattern transfer. First, DUV 252-330 material (an antireflective coating available from Brewer Science, Inc. Rolla, MO, US) was spun on each of two bare silicon wafers and baked (Layer 1). Then one of the SiHM-forming materials from Examples 5 and 6 was spun onto a respective one of the baked SOC layers and baked (Layer 2). Table 1 below provides additional processing conditions.

TABLE 1
[Processing Conditions for Formation of SOC and SiHM Layers.

| LAYER 1 | | | | LAYER 2 | | | |
|---|---|---|---|---|---|---|---|
| | | | Target | | | | Target |
| SOC | Spin | Bake | Thickness | SiHM | Spin | Bake | Thickness |
| DUV 252-330 | 880 rpm | 205° C. for | 400 nm | Formulation 1 | 1,382 rpm | 205° C. for | 50 nm |
| | for 30 secs | 60 secs | | Example 5 | for 30 secs | 60 secs | |
| DUV 252-330 | 880 rpm | 205° C. for | 400 nm | Formulation 2 | 1,382 rpm | 205° C. for | 50 nm |
| | for 30 secs | 60 secs | | Example 6 | for 30 secs | 60 secs | |

A commercially available KrF photoresist (sold under the name M91Y-9 cP by JSR Micro, Inc.) was spun on top of the SiHM formed from the materials in Examples 5 and 6 and a DUV lithography exposure and pattern transfer test was conducted according to the conditions set forth in Table 2.

TABLE 2
Processing Conditions for Lithography Test of Examples 5 and 6 Materials.

| PARAMETER | CONDITIONS |
|---|---|
| Resist: | M91Y-9cP |
| Resist thickness (nm): | 420 |
| Resist coat (rpm/sec): | 2,734/40 |
| Target CD (nm/pitch): | 160L/300P |
| Post-application bake (° C./sec): | 130/90 |
| Post-exposure bake (° C./sec): | 130/90 |
| Illumination mode: | Annular |
| Numerical aperture | 0.70 |
| Sigma (outer/inner): | 0.70/0.35 |
| Center dose/step (mJ/cm²): | 15/0.8 |
| Focus offset/step (μm): | 0.05/0.1 |
| Developer type/time (secs): | OPD262/60 |

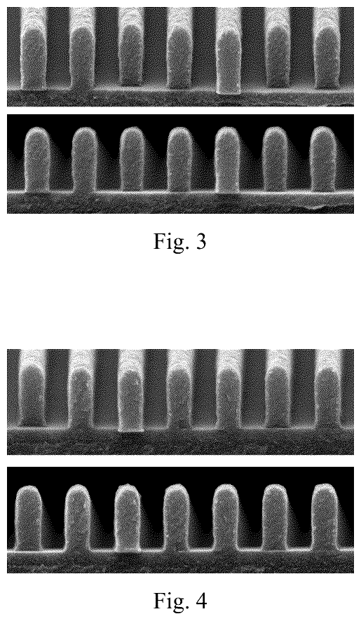

After the pattern had been developed in the resist of each sample using the Table 2 processes, scanning electron micrographs of each sectioned trilayer stack were taken at tilt angles of 75 and 90 degrees. These images are shown in FIG. 3 (Formulation 1 of Example 5) and FIG. 4 (Formulation 2 of Example 6).

### Example 9

### L/S Pattern Transfer Using the Material from Example 7

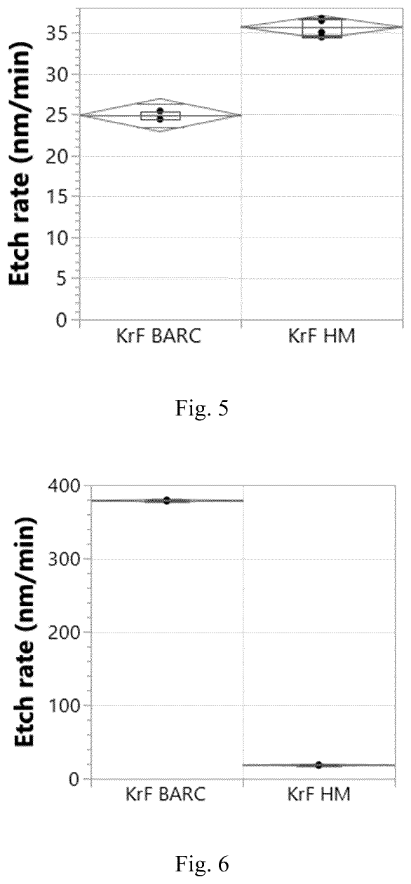

The formulation of Example 7 (i.e., Formulation 3) was used in a pattern transfer test for lines and spaces performed after DUV exposure using similar processing conditions as those in Example 8, except that DUV 42-360 material (an antireflective coating sold by Brewer Science, Inc., Rolla, MO, US) was used as the underlayer. FIG. 5 shows the etch rate comparison of the hardmask formed from the composition of Example 7 (“KrF HM” in FIG. 5) and the DUV 42 material underlayer (“KrF BARC” in FIG. 5) when CF₄ was used as the etchant. FIG. 6 shows the etch rate comparison of the hardmask formed from the composition of Example 7 (“KrF HM” in FIG. 5) and the DUV 42 material underlayer (“KrF BARC” in FIG. 5) when O₂/N₂ was used as the etchant. SOC opening recipe, for line space patterns: O₂/N₂=10/20, 20 mT, 500 W. For contact hole patterns: O₂/N₂=20/20, 20 mT, 500 W.

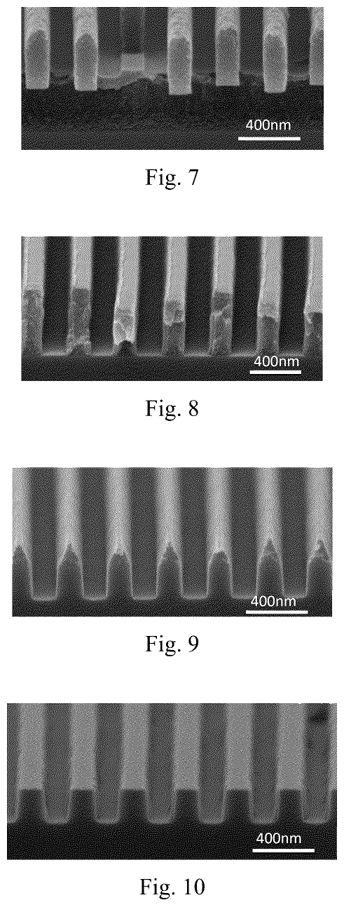

FIGS. 7-10 are SEMs of the pattern transfer steps for a hardmask formed from the material in Example 7 on DUV 42 material after hardmask open (FIG. 7), SOC open (FIG. 8), substrate open (FIG. 9), and O₂ ash steps (FIG. 10), respectively.

### Example 10

### Contact Hole Pattern Transfer Using the Material from Example 7

The material produced in Example 7 was used in an additional pattern transfer test for contact holes after DUV exposure with Brewer Science® GF 110K material (an underlayer, available from Brewer Science, Inc.). The processing conditions utilized are set forth in Tables 3 and 4 below.

TABLE 3
Processing Conditions for Formation of Underlayer and SiHM Layer.

| LAYER 1 | | | | LAYER 2 | | | |
|---|---|---|---|---|---|---|---|
| | | | Target | | | | Target |
| UNDERLAYER | Spin | Bake | Thickness | SiHM | Spin | Bake | Thickness |
| GF 110K-350 | 1,500 rpm | 205° C. for | 562 nm | Example 7 | 1,500 rpm | 205° C. for | 47 nm |
| | for 30 secs | 60 secs | | | for 30 secs | 60 secs | |
| GF 110K-350 | 1,500 rpm | 205° C. for | 562 nm | Example 7 | 1,500 rpm | 205° C. for | 97 nm |
| | for 30 sec | 60 secs | | | for 30 secs | 60 secs | |

TABLE 4
Processing Conditions for Lithography Test of Example 7 Material.

| PARAMETER | CONDITIONS |
|---|---|
| Resist: | M91Y-9cP |
| Resist thickness (nm): | 420 |
| Resist coat (rpm/sec): | 2,734/40 |
| Target CD (nm/pitch): | 160L/360P |
| Post-application bake (° C./sec): | 130/90 |
| Illumination mode: | Conventional |
| Numerical aperture | 0.70 |
| Sigma (outer/inner): | 0.70/0.35 |
| Center dose/step (mJ/cm²): | 27/0.8 |
| Focus offset/step (μm): | 0/0.08 |
| Post-exposure bake (° C./sec): | 130/90 |
| Developer type/time (secs): | OPD262/60 |

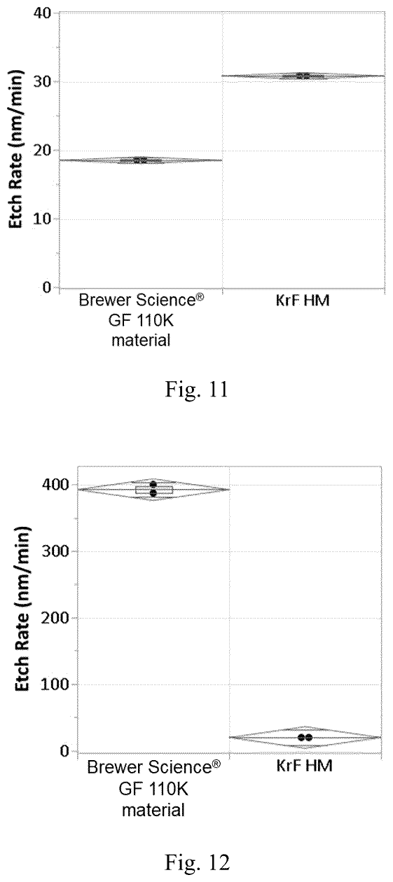

FIG. 11 shows the etch rate comparison of the hardmask formed from the composition of Example 7 (“KrF HM” in FIG. 11) and the GF 110K material underlayer when CF₄ was used as the etchant. FIG. 12 shows the etch rate comparison of the hardmask formed from the composition of Example 7 (“KrF HM” in FIG. 12) and the GF 110K material underlayer when O₂/N₂ was used as the etchant.

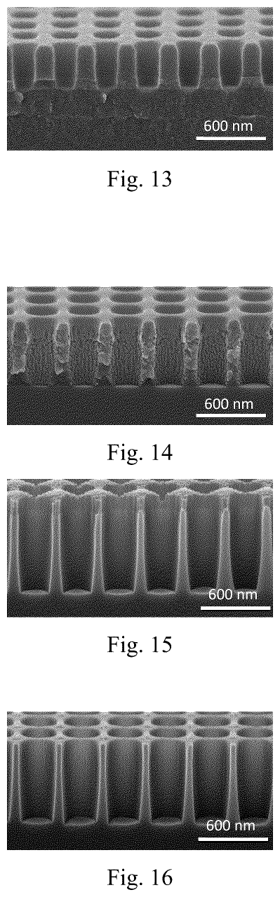

FIGS. 13-16 are SEMs of the pattern transfer steps for a hardmask formed from the material in Example 7 on GF 110K material after hardmask open (FIG. 13), SOC open (FIG. 14), substrate open (FIG. 15), and O₂ ash steps (FIG. 16), respectively.

1. A method of forming a microelectronic structure, said method comprising:
forming one or more intermediate layers on the surface of a substrate, said one or more intermediate layers comprising an uppermost intermediate layer;
applying a composition to said uppermost intermediate layer so as to form a silicon hardmask layer on said uppermost intermediate layer, said composition comprising a nonpolymeric siloxane and a polysiloxane dissolved or dispersed in a solvent system, wherein said nonpolymeric siloxane comprises a chromophore moiety;
forming a photoresist layer on said silicon hardmask layer; and
exposing at least a portion of said photoresist layer to radiation having a wavelength of about 100 nm to about 300 nm.

2. The method of claim 1, wherein said chromophore moiety is chosen from phenyl groups, naphthyl groups, anthracenyl groups, phenanthryl groups, fluorenyl groups, pyrenyl groups, chrysenyl groups, fluoranthenyl groups, benzofluorenyl groups, indenofluorenyl groups, perylenyl groups, or combinations thereof.

3. The method of claim 1, wherein said nonpolymeric siloxane comprises 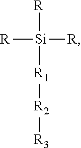
wherein:
each R is individually chosen from —H, alkoxys, or substituted or unsubstituted alkyls, with at least one R being an alkoxy;
R₁ comprises a substituted or unsubstituted alkylene group;
R₂ comprises a chemical unit formed by a reaction between an epoxide ring and a nucleophile; and
R₃ comprises said chromophore moiety.

4. The method of claim 1, wherein said nonpolymeric siloxane comprises the reaction product of a siloxane and a chromophore, wherein:
said siloxane is chosen from 2-(3,4-epoxycyclohexyl) ethyl trimethoxy silane, (3-glycidoxypropyl) trimethoxy silane, 5,6-epoxyhexyltriethoxysilane, (3-glycidoxypropyl) triethoxy silane, 3-glycidoxypropylmethyldiethoxysilane, 3-glycidoxypropylmethyldimethoxysilane, or 2-(3,4-epoxycyclohexyl)ethyltri-ethoxysilane; and
said chromophore is chosen from 1-hydroxy-2-naphthoic acid, 2-hydroxy-1-naphthoic acid, 6-hydroxy-2-naphthoic acid, 3-hydroxy-2-naphthoic acid, 1,4-dihydroxy-2-naphthoic acid, 3,5-dihydroxy-2-naphthoic acid, 3,7-dihydroxy-2-naphthoic acid, 3-hydroxy-2-anthracenecarboxylic acid, 1-hydroxy-2-anthracenecarboxylic acid, or 9-anthracenecarboxylic acid.

5. The method of claim 1, wherein said polysiloxane comprises:
an adhesion promoting monomer having a structure chosen from one or both of: 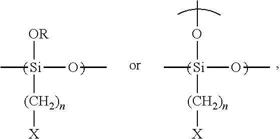
where:
each R is individually chosen from C₁ to about C₆ alkyls or —H;
n is 1 to about 6; and
each X is individually chosen from glycidoxy, epoxy, epoxycycloalkyls, succinic anhydride, acetamido, or isocyanurate moieties; and
one or both of the following:
a surface modification monomer having a structure chosen from one or both of: 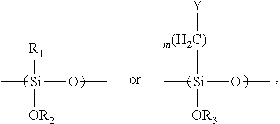
where:
each R₁ is individually chosen from C₁ to about C₆ alkyls or C₆ to about C₂₀ aryls;
each R₂ is individually chosen from C₁ to about C₆ alkyls or —H;
each R₃ is individually chosen from C₁ to about C₆ alkyls or —H;
m is 1 to about 6; and
each Y is individually chosen from acetoxy, ester, or aryl moieties; or
a densification monomer having a structure chosen from one, two, or three of: 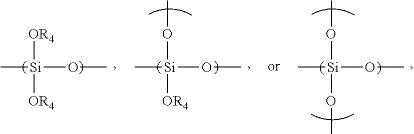
where each R₄ is individually chosen from C₁ to about C₆ alkyls or —H.

6. The method of claim 1, wherein said polysiloxane comprises recurring monomers chosen from tetraethoxysilane, methyltrimethoxysilane, phenyltrimethoxysilane, 2-(3,4-epoxycyclohexyl) ethyl trimethoxy silane, or combinations thereof.

7. The method of claim 1, wherein the weight ratio of nonpolymeric siloxane to polysiloxane is about 1:5 to about 1:1.

8. The method of claim 1, wherein said uppermost intermediate layer is a carbon-rich layer comprising about 50% by weight or greater carbon, based on the weight of the carbon-rich layer taken as 100% by weight.

9. The method of claim 1, wherein said composition comprises less than about 2% by weight of a polymer other than said polysiloxane.

10. The method of claim 1, wherein said nonpolymeric siloxane has a weight average molecular weight of 900 Daltons or lower.

11. The method of claim 1, wherein one, two, or three of the following are true:
said polysiloxane comprises a polymer backbone that does not include any ringed structures therein;
said composition does not include any silsesquioxane resins; or
said polysiloxane does not include pendant groups that comprise conjugated functional groups.

12. The method of claim 1, wherein said uppermost intermediate layer is not a dielectric layer.

13. The method of claim 1, wherein said applying comprises heating said composition so as to crosslink said polysiloxane to form said silicon hardmask layer.

14. A microelectronic structure comprising:
a substrate having a surface;
one or more intermediate layers on said surface, there being an uppermost intermediate layer;
a silicon hardmask layer on said uppermost intermediate layer, said silicon hardmask layer comprising a polysiloxane and a nonpolymeric siloxane comprising a chromophore moiety, said polysiloxane being self-crosslinked and crosslinked with said nonpolymeric siloxane; and
a photoresist layer on said silicon hardmask layer.

15. The microelectronic structure of claim 14, wherein said silicon hardmask layer comprises less than about 2% by weight of a polymer that is not a polysiloxane, based on the weight of the silicon hardmask layer taken as 100% by weight.

16. The microelectronic structure of claim 14, wherein said chromophore moiety is chosen from phenyl groups, naphthyl groups, anthracenyl groups, phenanthryl groups, fluorenyl groups, pyrenyl groups, chrysenyl groups, fluoranthenyl groups, benzofluorenyl groups, indenofluorenyl groups, perylenyl groups, or combinations thereof.

17. The microelectronic structure of claim 14, wherein said nonpolymeric siloxane comprises 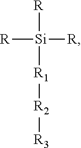
wherein:
each R is individually chosen from —H, alkoxys, or substituted or unsubstituted alkyls, with at least one R being an alkoxy;
R₁ comprises a substituted or unsubstituted alkylene group;
R₂ comprises a chemical unit formed by a reaction between an epoxide ring and a nucleophile; and
R₃ comprises said chromophore moiety.

18. The microelectronic structure of claim 14, wherein said nonpolymeric siloxane comprises the reaction product of a siloxane and a chromophore, wherein:
said siloxane is chosen from 2-(3,4-epoxycyclohexyl) ethyl trimethoxy silane, (3-glycidoxypropyl) trimethoxy silane, 5,6-epoxyhexyltriethoxysilane, (3-glycidoxypropyl) triethoxy silane, 3-glycidoxypropylmethyldiethoxysilane, 3-glycidoxypropylmethyldimethoxysilane, or 2-(3,4-epoxycyclohexyl)ethyltri-ethoxysilane; and
said chromophore is chosen from 1-hydroxy-2-naphthoic acid, 2-hydroxy-1-naphthoic acid, 6-hydroxy-2-naphthoic acid, 3-hydroxy-2-naphthoic acid, 1,4-dihydroxy-2-naphthoic acid, 3,5-dihydroxy-2-naphthoic acid, 3,7-dihydroxy-2-naphthoic acid, 3-hydroxy-2-anthracenecarboxylic acid, 1-hydroxy-2-anthracenecarboxylic acid, or 9-anthracenecarboxylic acid.

19. The microelectronic structure of claim 14, wherein said polysiloxane comprises:
an adhesion promoting monomer having a structure chosen from one or both of: 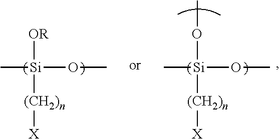
where:
each R is individually chosen from C₁ to about C₆ alkyls or —H;
n is 1 to about 6; and
each X is individually chosen from glycidoxy, epoxy, epoxycycloalkyls, succinic anhydride, acetamido, or isocyanurate moieties; and
one or both of the following:
a surface modification monomer having a structure chosen from one or both of: 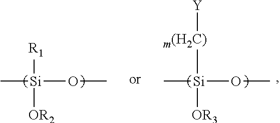
where:
each R₁ is individually chosen from C₁ to about C₆ alkyls or C₆ to about C₂₀ aryls;
each R₂ is individually chosen from C₁ to about C₆ alkyls or —H;
each R₃ is individually chosen from C₁ to about C₆ alkyls or —H;
m is 1 to about 6; and
each Y is individually chosen from acetoxy, ester, or aryl moieties; or
a densification monomer having a structure chosen from one, two, or three of: 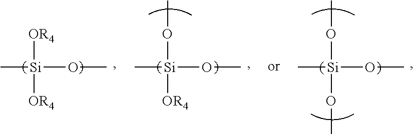
where each R₄ is individually chosen from C₁ to about C₆ alkyls or —H.

20. The microelectronic structure of claim 14, wherein said polysiloxane comprises recurring monomers chosen from tetraethoxysilane, methyltrimethoxysilane, phenyltrimethoxysilane, 2-(3,4-epoxycyclohexyl) ethyl trimethoxy silane, or combinations thereof.

21. The microelectronic structure of claim 14, wherein said uppermost intermediate layer is a carbon-rich layer comprising about 50% by weight or greater carbon, based on the weight of the carbon-rich layer taken as 100% by weight.

22. The microelectronic structure of claim 14, wherein one, two, or three of the following are true:
said polysiloxane comprises a polymer backbone that does not include any ringed structures therein;
said silicon hardmask layer does not include any silsesquioxane resins; or
said polysiloxane does not include pendant groups that comprise conjugated functional groups.

23. The microelectronic structure of claim 14, wherein said uppermost intermediate layer is not a dielectric layer.

24. A composition for forming a silicon hardmask layer for deep ultraviolet lithography comprising a polysiloxane and a nonpolymeric siloxane dissolved or dispersed in a solvent system, said nonpolymeric siloxane comprising a chromophore moiety.

25. The composition of claim 24, wherein said nonpolymeric siloxane comprises 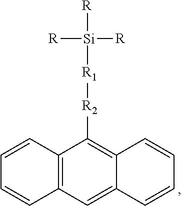
wherein:
each R is individually chosen from —H, alkoxys, or substituted or unsubstituted alkyls, with at least one R being an alkoxy;
R₁ comprises a substituted or unsubstituted alkylene group; and
R₂ comprises a chemical unit formed by a reaction between an epoxide ring and a nucleophile.

26. The composition of claim 24, wherein:
siloxane is chosen from 2-(3,4-epoxycyclohexyl) ethyl trimethoxy silane, (3-glycidoxypropyl) trimethoxy silane, 5,6-epoxyhexyltriethoxysilane, (3-glycidoxypropyl) triethoxy silane, 3-glycidoxypropylmethyldiethoxysilane, 3-glycidoxypropylmethyldimethoxysilane, or 2-(3,4-epoxycyclohexyl)ethyltriethoxysilane; and
said chromophore moiety is chosen from phenyl groups, naphthyl groups, anthracenyl groups, phenanthryl groups, fluorenyl groups, pyrenyl groups, chrysenyl groups, fluoranthenyl groups, benzofluorenyl groups, indenofluorenyl groups, or perylenyl groups.
